(19) United States
(12) Patent Application Publication
(10) Pub. No.: US 2016/0066434 A1
(43) Pub. Date: Mar. 3, 2016

(54) CIRCUIT BOARD AND METHOD OF MANUFACTURING CIRCUIT BOARD

(71) Applicant: SAMSUNG ELECTRO-MECHANICS CO., LTD., Suwon-Si (KR)

(72) Inventors: Seong Min CHO, Gwangmyeong-si (KR); Jung Youn KIM, Changwon-si (KR); Sang Kun KIM, Anyang-si (KR)

(73) Assignee: SAMSUNG ELECTRO-MECHANICS CO., LTD., Suwon-si (KR)

(21) Appl. No.: 14/813,695

(22) Filed: Jul. 30, 2015

(30) Foreign Application Priority Data
Sep. 3, 2014 (KR) 10-2014-0116683

(51) Int. Cl. H05K 3/18; H05K 3/26; H05K 3/00; H05K 1/02; H05K 3/46

(52) U.S. Cl. CPC H05K 3/181; H05K 1/0298; H05K 3/46; H05K 3/0073; H05K 3/26

(57) ABSTRACT

The circuit board provided with a first conductive pattern and a second conductive pattern performed by different types of surface treatments are disclosed. The circuit board in accordance with one embodiment of the present invention forms the first conductive pattern and the second conductive pattern on an insulating layer, wherein the first metal plating layer and the second metal plating layer are formed on the surface of the first conductive pattern, the second metal plating layer is formed on the surface of the second conductive pattern, and the second metal plating layer is made of the material different from that of the first metal plating layer to be exposed to the outside, whereby the pattern pitch is easily reduced, the reduction of the electrical characteristics due to the surface treatment can be minimized and the efficiency of the manufacturing process may be improved.

### CROSS REFERENCE TO RELATED APPLICATION

This application claims the benefit under 35 U.S.C. Section 119 of Korean Patent Application Serial No. 10-2014-0116683, entitled filed Sep. 3, 2014, which is hereby incorporated by reference in its entirety into this application.

### BACKGROUND OF THE INVENTION

1. Field of the Invention

The embodiment of the present invention relates to a circuit board.

2. Description of the Related Art

Various circuit patterns are provided inside or outside of a circuit board. In general, a surface treatment such as plating is performed to protect the circuit patterns to be exposed to the outside among such circuit patterns or to improve the connection reliability with the other elements.

Such surface treatment are an electroplating, an electroless plating, an OSP (Organic Solderbility Preservative) process or the like, they are introduced in various references such as patent documents 1 to 3.

### SUMMARY OF THE INVENTION

The present invention has been invented in order to overcome the above-described problems and it is, therefore, an object of the present invention to provide a circuit board provided with a conductor pattern which is performed with various different types of surface treatments.

And, it is another object of the present invention to provide a method of manufacturing a circuit board improved in the efficiencies of surface treatment processes.

Technical objects of the present invention are not limited to the above-mentioned ones, and other technical objects not mentioned above would clearly be understood by those skilled in the art through the following description.

In accordance with one aspect of the present invention to achieve the object, there is provided a circuit board provided with a first conductive pattern and a second conductive pattern.

In accordance with another aspect of the present invention, the first conductive pattern and the second conductive pattern perform the function as the connection pad to electrically connect the circuit board with other electronic components. At this time, the first conductive pattern may be wire bonded or solder bonded to other electronic components.

In one embodiment of the present invention, the first metal plating layer is formed on the first conductive pattern and the second metal plating layer is formed on the second conductive pattern. Herein, the first metal plating layer and the second metal plating layer are formed of different metals.

In one embodiment of the present invention, the outermost insulating layer may be formed on at least a portion among the external surface of the circuit board, and the outermost insulating layer can expose at least a portion of each of the first conductive pattern and the second conductive pattern. At this time, the outermost insulating layer may be formed of the solder resist, the first metal plating layer is formed on the surface of the first conductive pattern exposed to the outside of the outermost insulating layer, and the second metal plating layer may be formed on the outer surface of the first metal plating layer. Whereas the second plating layer may be formed on the surface exposed to the outside of the outermost insulating layer among the surface of the second conductive pattern.

In one embodiment of the present invention, the third metal plating layer is formed on the external surface of the first metal plating layer being in contact with the surface of the first conductive pattern and the second metal plating layer may be formed on the external surface of the third metal plating layer.

A method of manufacturing a circuit board in accordance with an exemplary embodiment of the present invention performs the steps of plating with the first metal at the state that the mask pattern to shield the second conductive pattern is formed with exposing the first conductive pattern and plating with the second metal at the state that the mask pattern is removed.

At this time, before the removing the mask pattern, a step of plating with the third metal at the external surface of the first metal plating layer can be further performed.

And also, before performing the plating with the second metal, the process of cleaning with an acid solution may be in advance.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view schematically showing a circuit board in accordance with an embodiment of the present invention;

As FIG. 2A and FIG. 2B are process cross-sectional views schematically showing a method of manufacturing a circuit board in accordance with an embodiment of the present invention,

FIG. 2A is a cross-sectional view exemplifying a state to form a mask;

FIG. 2B is a cross-sectional view exemplifying a state to pattern a mask;

FIG. 2C is a cross-sectional view exemplifying a state to plate a first metal and a third metal;

FIG. 2D is a cross-sectional view exemplifying a state to remove the mask; and

FIG. 2E is a cross-sectional view exemplifying a state to plate a second metal; and

FIG. 3 is a diagram schematically showing a method of manufacturing a circuit board in accordance with one embodiment of the present invention.

### DETAILED DESCRIPTION OF THE PREFERABLE EMBODIMENTS

Advantages and features of the present invention and methods of accomplishing the same will be apparent by referring to embodiments described below in detail in connection with the accompanying drawings. However, the present invention is not limited to the embodiments disclosed below and may be implemented in various different forms. The exemplary embodiments are provided only for completing the disclosure of the present invention and for fully representing the scope of the present invention to those skilled in the art. Like reference numerals refer to like elements throughout the specification.

Terms used in the present specification are provided to explain embodiments, not limiting the present invention. Throughout this specification, the singular form includes the plural form unless the context clearly indicates otherwise. When terms “comprises” and/or “comprising” used herein do not preclude existence and addition of another component, step, operation and/or device, in addition to the above-mentioned component, step, operation and/or device.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “in one embodiment” herein do not necessarily all refer to the same embodiment.

Hereinafter, the configurations and the operational effects of the present invention will be described in detail with reference to the accompanying drawings.

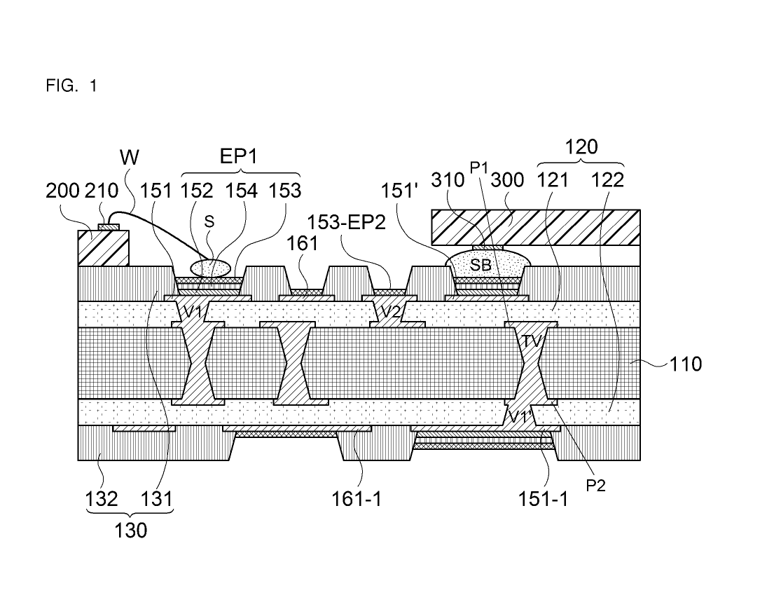

FIG. 1 is a cross-sectional view schematically showing a circuit board 100 in accordance with an embodiment of the present invention.

Referring to FIG. 1, the circuit board 100 in accordance with the embodiment of the present invention includes a first conductive pattern 151 and a second conductive pattern 161, wherein the first conductive pattern 151 and the second conductive pattern 161 are performed with different surface treatments.

Accordingly, according to performing each of the surface treatments, a first surface treatment part EP1 is formed on a first conductive pattern 151, a second surface treatment part EP2 is formed on a second conductive pattern 161, and the first surface treatment part EP1 and the second surface treatment part EP2 are different from each other in their materials, layer structure, heights and material properties.

In one embodiment, the first conductive pattern 151 and the second conductive pattern 161 can perform the function of connection pads at the circuit board 100. That is, the first conductive pattern 151 and the second conductive pattern 161 may be formed on the surface of the insulating layer 110 or the build-up insulating layer 120. And also, an outermost insulating layer 130 to cover at least a portion of each of the first conductive pattern 151 and the second conductive pattern 161 and the surface of the insulating layer 110 or the build-up insulating layer 120 may be formed. And, at least a portion of each of the first conductive pattern 151 and the second conductive pattern 161 may be exposed to the outside of the outermost insulating layer 130. At this time, the surface treatment may be performed at the surface of the first conductive pattern 151 and the surface of the second conductive pattern 161 exposed to the outside of the outermost insulating layer 130.

On the other hands, the circuit board 100 may be implemented by forming the circuit pattern made of the conductive material on one surface of both surfaces thereof. In this case, the first conductive pattern 151 and the second conductive pattern 161 may be included at the circuit pattern.

And also, the circuit board can include an inner layer pattern. That is, a first inner layer pattern P1 may be formed on one surface of the insulating layer 110; and, further, a second inner layer pattern P2 may be formed on the other surface of the insulating layer 110. At this time, the first inner layer pattern P1 and the second inner layer pattern P2 may be electrically connected by a through via TV penetrating the insulating layer 110.

On the other hands, the build-up insulating layer 120 may be further included in order to cover the insulating layer 110 and the inner layer patterns P1 and P2. That is, a top build-up insulating layer 121 may be included to cover a top surface of the insulating layer and the first inner layer pattern P1; and, further, a bottom build-up insulating layer 122 may be included to cover a bottom surface of the insulating layer 110 and the second inner layer pattern P2. In this case, the first conductive pattern 151 and the second conductive pattern 161 are included into the circuit patterns formed on the external surface of the build-up insulating layer 120. And also, the first conductive pattern 151 may be electrically connected to the first inner layer pattern P1 by the via V1 penetrating the top build-up insulating layer 121. And, the second conductive pattern 161 may be electrically connected to the first inner pattern P1 by the via V2 penetrating the top build-up insulating layer 121. The first conductive pattern 151-1 or the second conductive pattern 161-1 may be formed on the surface of the bottom build-up insulating layer 122 and the first conductive pattern 151-1 may be electrically connected to the second inner layer pattern P2 by the via V′ penetrating the bottom build-up insulating layer 122.

And also, the outermost insulating layer 130 made of a solder resist or the like may be further included on the outer surface of the build-up insulating layer 120, and at least a part among the first conductive pattern 151 and at least a part among the second conductive pattern may be exposed to the outside of the outermost insulating layer 130.

On the other hands, a wire W may be coupled to the second metal plating layer 153 formed on a top side of the first conductive pattern 151 by a solder S, and an external terminal 210 of a second electronic component 200 such as IC may be connected to the other end of the wire W. And also, an external electrode 310 of a third electronic component 30 may be connected to the second metal plating layer 153 formed on the top side of the first conductive pattern 151′ by a solder ball SB.

In the embodiment of the present invention, the combination of the first surface treatment part EP1 and the second surface treatment part EP2 may be two different types of combinations selected from a group consisting of ENIG (Electroless Ni Immersion Gold), ENEPIG (Electroless Ni Electroless Pd Immersion Gold), EPIG (Electroless Pd Immersion Gold), DIG (Direct Immersion Gold), Immersion Sn, Immersion Ag, Ni, Pd, Au, Sn, Ag or the like.

And also, if the layer exposed from the first surface treatment part EP1 and the second surface treatment part EP2 to the outside is gold (Au), the first surface treatment part EP1 and the second surface treatment part EP2 can be realized by the combination of ENEPIG & EPIG, ENEPIG&DIG, ENIG&DIG and EPIG&DIG.

The circuit board 100 in accordance with one embodiment of the present invention can improve the efficiency with satisfying the required conditions according to performing such different surface treatments.

For example, if the gold plating layer is formed on the outermost region of the connection pad, it is appropriate to implement the wire bonding. However, the wire bonding is performed for only a portion among the connection pads provided on the external surface of the circuit board, and the wire bonding is not performed for the remaining portion. Herein, the gold plating is performed only the connection pad to implement the wire bonding and the gold plating cannot be performed at the connection pad where the wire bonding is not performed. Accordingly, since the gold plating is applied to only the required connection pad, the usage of gold can be saved.

On the other hands, the Ni plating layer to be widely used as the surface treatment part is formed relatively thick, if all the connection pads can be implemented with such thick Ni plating layer, the limitation is generated for the fineness of the connection pads. And also, if the Ni is included in the surface treatment part, the electrical characteristics becomes low relatively; and, if the Ni plating layer is also implemented to the unnecessary connection pads, the electric characteristics decreases unnecessarily. Accordingly, if the Ni plating layer is formed al the connection pads at the state that the connection pads to require the Ni plating layer and the connection pads not to require the Ni plating layer among various connection pads formed on one surface of the circuit board 100 coexist, the unnecessary limitation for the fineness of the connection pads is generated or the problem to reduce the electrical characteristics unnecessarily may be generated.

However, the circuit board 100 in accordance with one embodiment of the present invention implements the surface treatment part including the Ni plating layer for a part among the connection pads, and the remaining part among the connection pads can implement the surface treatment part not to include the Ni plating layer. That is, in the above-described first conductive pattern 151, while the Ni plating layer is included as the first metal plating layer 152 and the gold plating layer is included as the second metal plating layer, in the second conductive pattern 161, the gold plating layer can be included as the second metal plating layer 153. Herein, the connection pads requiring the fineness of the pattern width or the pattern pitch implements as the above-described second conductive pattern 161, and the connection pads to be in contact with the solder paste or the solder ball may be implemented with the above-described first conductive pattern 151. Accordingly, the circuit board 100 in accordance with the embodiment of the present invention can minimize the limitation at the aspect of the fineness of the connection pads or the unnecessary reduction problem of the electric characteristics can be minimized.

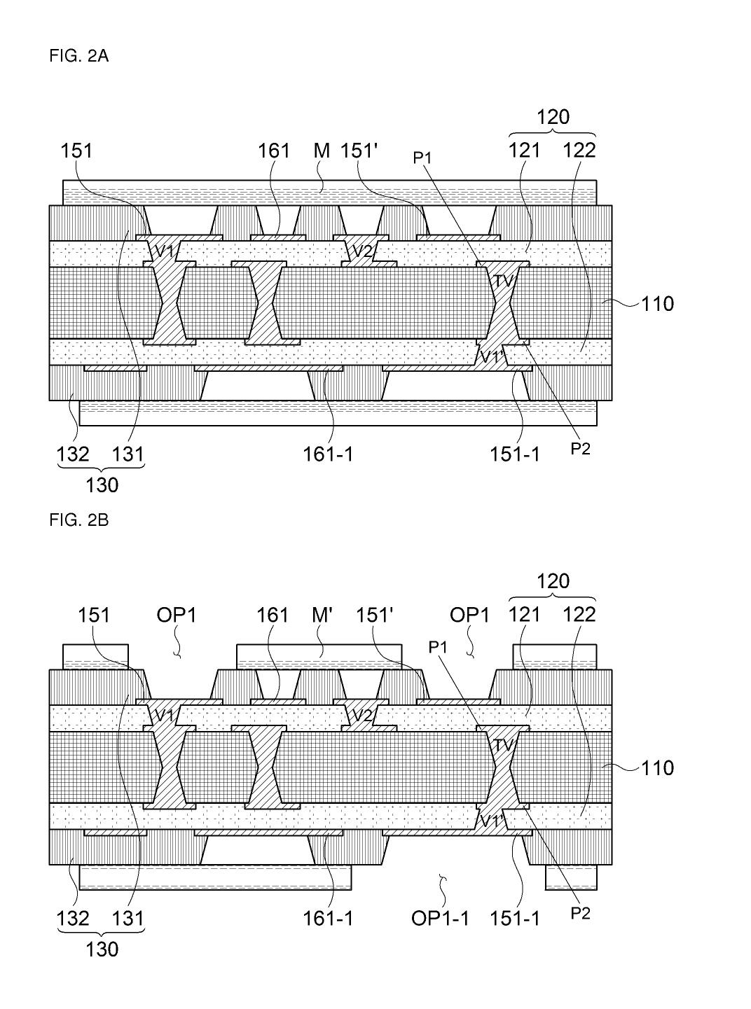

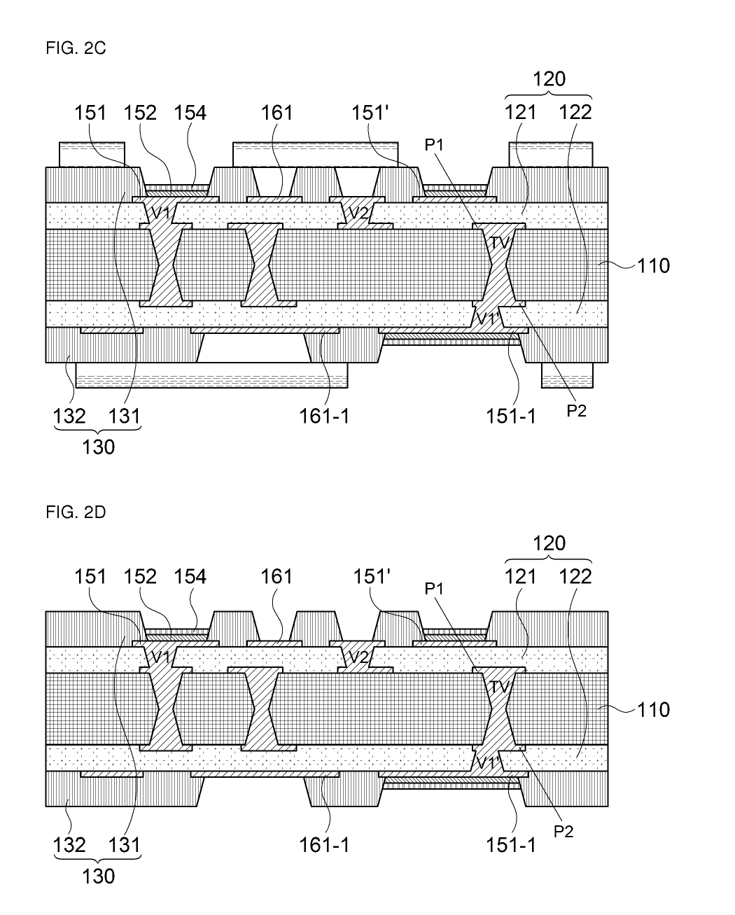

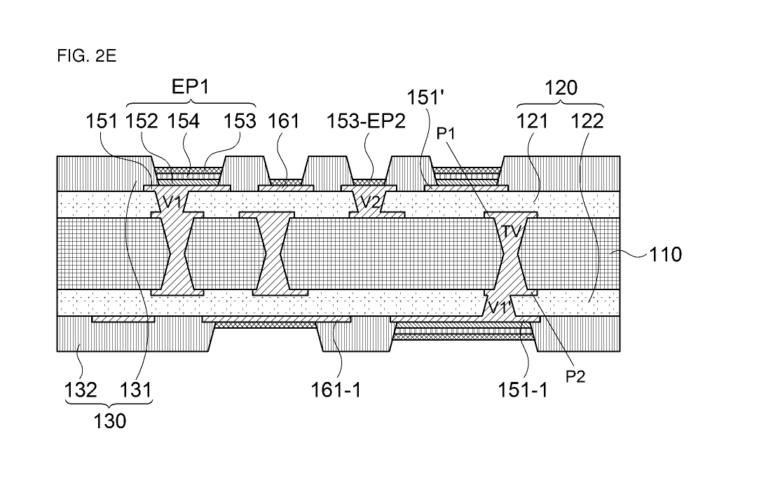

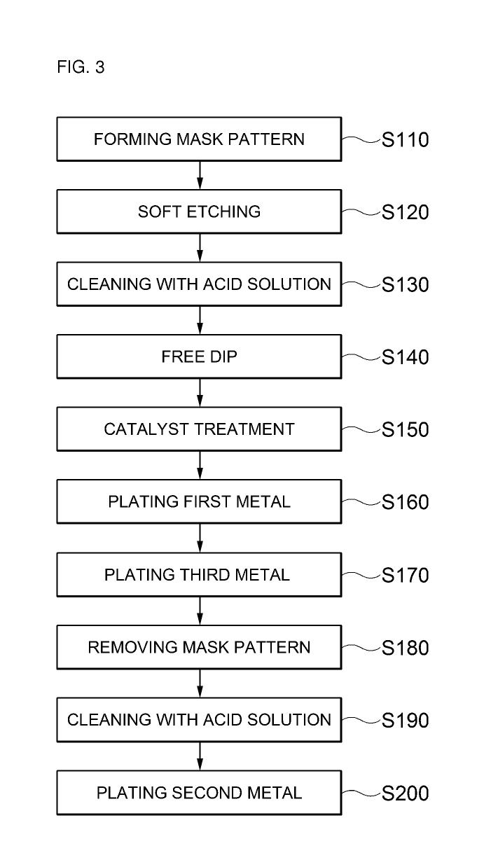

As FIG. 2A and FIG. 2B are process cross-sectional views schematically showing a method of manufacturing a circuit board in accordance with an embodiment of the present invention, and FIG. 3 is a diagram schematically showing a method of manufacturing a circuit board in accordance with one embodiment of the present invention.

Referring to FIG. 1 to FIG. 3, a method of manufacturing a circuit board 100 in accordance with an embodiment of the present invention may be implemented by forming a mask pattern on the circuit board 100 provided with a first conductive pattern 151 and a second conductive pattern 161, after performing the plating with a first metal, removing the mask pattern, and performing the plating with a second metal. At this time, before removing the mask pattern, the plating can be further performed with a third metal as occasion demands. And also, after removing the mask pattern, a step of cleaning with an acid solution may be further performed before performing the plating with the second metal.

First, referring to FIG. 2A, a mask M is formed on the circuit board provided with the first conductive pattern 151 and the second conductive pattern 161.

Next, referring to FIG. 2B, the mask is patterned in such a way that the opening units OP1 and OP1-1 are formed on the top region of the first conductive pattern 151. Herein, as the opening units are not formed on the top region of the second conductive pattern 161, the second conductive pattern 161 is sealed by the mask M.

At this time, after forming the mask pattern (S110), after being cleaned with the acid solution (S130), a free dip (S140), a catalyst treatment (S150) or the like further performed, the following first metal plating process (S160) may be further performed.

Next, referring to FIG. 2C, at the state where the mask pattern is formed, the plating process is performed with the first metal. At this time, the first metal can include the Ni, and the third metal is sequentially plated (S170) as occasion demands. For example, the third metal may be Pd.

Thereafter, referring to FIG. 2D, the mask pattern is removed (S180).

And then, referring to FIG. 2E, the second metal is plated on the exposed surfaces of the first metal plating layer 152 or the third metal plating layer 154 formed on the top of the first conductive pattern 151 and the surface of the second conductive pattern 161 exposed to the outside according to removing the mask pattern.

On the other hands, before performing the plating with the second metal (S200), a step of cleaning with the acid solution (S190) can be further performed. Accordingly, in case when the second conductive pattern 161 is made of copper and the second metal plating layer 153 is made of gold, the efficiency of the plating may be improved.

And also, between the above-described processes, so-called cleaning processes may be performed to clean the intermediate products with water.

According to the above-described method, the circuit board performed with different surface treatments may be efficiently manufactured.

In accordance with one embodiment of the present invention, the pattern pitch of the circuit board can be reduced, the reduction of the electrical characteristics due to the surface treatment can be minimized and the efficiency of the manufacturing process can be improved.

What is claimed is:

1. A circuit board comprising:
an insulating layer;
a first conductive pattern formed on a surface of the insulating layer and provided with a first metal plating layer and a second metal plating layer; and
a second conductive pattern formed on the surface of the insulating layer and provided with a second metal plating layer,
wherein the first metal plating layer and the second metal plating layer are made of different metals.

2. The circuit board according to claim 1, wherein the first metal plating layer is in contact with a surface of the first conductive pattern and the second metal plating layer is in contact with the second conductive pattern.

3. The circuit board according to claim 1, wherein the second metal plating layer is exposed to an outside of the circuit board.

4. The circuit board according to claim 1, wherein the first metal plating layer is formed on a surface of the first conductive pattern and the second metal plating layer is formed on a surface of the first metal plating layer.

5. The circuit board according to claim 1, wherein the first metal plating layer is formed on a surface of the first conductive pattern, a third metal plating layer is formed on a surface of the first metal plating layer, the first metal layer is formed on a surface of the third metal plating layer and the third metal plating layer is made of a material different from the first metal plating layer and the second metal plating layer.

6. The circuit board according to claim 1, wherein a shortest distance from a top surface of the first conductive pattern to a top surface of the second metal plating layer is larger than a shortest distance from a top surface of the second conductive pattern to a top surface of the second metal plating layer.

7. A method of manufacturing a circuit board comprising:
supplying a circuit board provided with a first conductive pattern and a second conductive pattern on an insulating layer;
forming a mask pattern to cover the second conductive pattern with exposing the top of the first conductive pattern;
performing a plating with a first metal;
removing the mask pattern; and
performing a plating with a second metal.

8. The method of manufacturing the circuit board according to claim 7, wherein the first metal includes nickel and the second metal includes gold.

9. The method of manufacturing the circuit board according to claim 7, after performing the plating with the first metal, further comprises:
performing a plating with a third metal; and
removing the mask pattern.

10. The method of manufacturing the circuit board according to claim 7, between removing the mask pattern and performing the plating with the second metal, further comprises:
cleaning with an acid solution.
